(19) United States
(12) Patent Application Publication
(10) Pub. No.: US 2008/0164524 A1
(43) Pub. Date: Jul. 10, 2008

(54) Optical mask employed for manufacturing array substrate, array substrate and method for manufacturing the same

(75) Inventors: Hideo Kawano, Kanagawa-ken (JP); Hideki Sunayama, Tokyo-to (JP)

Correspondence Address: Nields & Lemack, 176 E. Main Street, Suite #5, Westboro, MA, 01581, US

(73) Assignee: InfoVision Optoelectronics Holdings Limited, Tortola (VG)

(21) Appl. No.: 12/002,704

(22) Filed: Dec. 18, 2007

(30) Foreign Application Priority Data
Dec. 19, 2006 (JP) 2006-341870

(51) Int. Cl. H01L 27/12; G03F 1/00; H01L 21/84

(52) U.S. Cl. 257/347; 430/5; 438/151; 257/E21.7; 257/E27.112

(57) ABSTRACT

The invention provides wiring, which can form or disconnect freely the adjacent exposure regions by employing the same optical mask under a condition that a plurality of array substrates are produced on one mother glass substrate; and an optical mask, which can be inspected by utilizing the same probe device for inspecting even though under a condition that the same mother glass substrate is used to produce the array substrates with different sizes; array substrates; and the manufacture method of the same. The solution means is: the above optical mask is formed to allow: the wiring in upper section at up and down direction is formed in the upper end section of the array substrate, and the wiring in lower section at up and down direction is formed in the lower end section; and a “U shape turning section towards the boundary”, which is turned in a U shape to the boundary at the lower end side of said array substrate, is formed, and a “U shape turning section towards the center”, which is turned again in a U shape to the center section of said array substrate, is formed.

### FIELD OF THE INVENTION

The invention relates to an optical mask of an array substrate employed for manufacturing the liquid crystal display device, an array substrate and a method for manufacturing the same.

### DESCRIPTION OF THE RELATED ART

Array substrates used for the display device of the liquid crystal display device uses normally large mother glass substrate for manufacturing a plurality of array substrates, that is, a plurality of array substrates can be obtained from one mother glass substrate. Under the condition that the respective array substrates are inspected after the array substrates being manufactured from a mother glass substrate, the inspection probes, which are connected electrically with the inspection pads disposed at the peripheral of the mother glass substrate, are used for inspecting. At this time, even if the sizes of the array substrates are different or the number of the array substrates obtained from one mother glass substrate is different, the same probe block (It is a device in which the probes for inspecting are embedded therein according to the positions of the inspection pads) used for inspecting can be employed as long as the positions of the pads disposed at the peripheral of the mother glass substrate are the same, in this way, the expenses can be saved, and the productivity can be increased simultaneously. Therefore, under a condition that the sizes of the array substrates, or the number of the array substrates obtained form one mother glass substrate are different, the pads used for inspecting are arranged at as same a position as possible, and an universal probe device for inspecting can be obtained.

However, under the conditions that the array substrates of 17 inches is manufactured by using one mother glass substrate and the array substrates of 19 inches is manufactured by using one mother glass substrate, the positions of the pads for inspecting disposed at the peripheral of the mother glass substrate are different, the same probe device for inspecting cannot be used. The reason is that under the condition in which the 19-inch-array substrates are configured on the same mother glass substrate for configuring the 17-inch-array substrates, the positions of the inspection points are changed by comparing with the condition in which the 17-inch-array substrates are configured on the mother glass substrate, the wiring for connecting the inspection points of the array substrates of the 19-inch-array substrates with the pads for inspecting at the peripheral of the mother glass substrate cannot be used as that is used under the 17-inch-array substrates condition. It will be described according to the figures as follows.

FIG. 1 is a plan view of a mother glass substrate showing a general situation that the pads used for inspecting are disposed on the mother glass substrate.

In FIG. 1, 101 is a mother glass substrate, 102 is a pad used for inspecting, 121˜123 are the sets formed by a plurality of inspection pads corresponding respectively to one array substrate (Hereinafter referred to as “inspection pad set”). 131˜133 are also inspection pad sets used respectively for inspecting one array substrate.

FIG. 7 is a plan outline view of the mother glass substrate under a condition that twelve pieces of 17-inch-array substrates are disposed on the same mother glass substrate as that in FIG. 1.

In FIG. 7, 711˜713 are the 17-inch-array substrates, which are disposed on the upmost section of the mother glass substrate, 721˜723 are the array substrates which are disposed on the second section of the mother glass substrate beginning from the upmost section, 731˜733 are the array substrates disposed on the third section of the mother glass substrate beginning from the upmost section, 741˜743 are the array substrates disposed on the fourth section of the mother glass substrate beginning from the upmost section, 751 and 752 are the exposure regions which are exposed by one piece of optical mask, respectively, 121˜123, 791, 792 and 131˜133 are the inspection pad sets, 761 is an inspection pad included in the inspection pad set 121, 762 is an inspection pad included in the inspection pad set 791, 763 is an inspection pad included in the inspection pad set 792, 764 is an inspection pad included in the inspection pad set 131, 771 is an inspection point of the array substrate 711, 772 is an inspection point of the array substrate 731, 781 is wiring for connecting the inspection pad 761, the inspection pad 771 of the array substrate 711, and the inspection pad 762, 782 is wiring for connecting the inspection pad 763, the inspection pad 772 of the array substrate 731, and the inspection pad 764.

Under the condition of the mother glass substrate as shown in FIG. 7, in order to inspect the array substrate 771 disposed on the upper section of the mother glass substrate by means of using the inspection point 771, the probe device should be contacted with the inspection pad 761. At this time, the inspection pad 761 is also connected with the inspection pad 762 that is not used for inspecting via the wiring 781, however, because the inspection pad set 791 disposed on the middle section of the mother glass substrate is not used, so the inspection pad 762 is not employed, and an electrical open state is formed, therefore no any bad effects will be occurred upon the inspection using the inspection pad 761. Next, for the array substrate 731, which is disposed on the lower section of the mother glass substrate, in order to inspect it via the inspection point 772 of the array substrate 731, the probe block should be contacted with the underlying inspection pad 764. At this time, the inspection pad 764 is also connected with the inspection pad 763 that is not used for inspecting via the wiring 782, however, because the inspection pad set 792 disposed on the middle section of the mother glass substrate is not used, so the inspection pad 763 is not employed, therefore no any bad effects will be occurred upon the inspection using the inspection pad 764.

That is, if the wiring, which connects the respective inspection points of the array substrate 711 or 712 to the inspection pads of both of the inspection pad set 791 at the upper side and the inspection pad set 791 at the lower side in a exposure region like the wiring 781, is disposed in advance, then under a condition in which the exposure regions 751 and 752 are exposed by using the same optical mask, the array substrates 711, 721 disposed at the upper side and the array substrates 731, 741 disposed at the lower side are manufactured, and the array substrates 711 or 721 disposed at the upper side of the mother glass substrate 101 are inspected, any inspection pads in the inspection pad set 121 at the upper section of the mother glass substrate 101 can be used for inspecting, under a condition in which the array substrates 731 or 741 disposed at the lower section of the mother glass substrate 101 are inspected, any inspection pads in the inspection pad set 131 at the lower section of the mother glass substrate 101 can be used for inspecting.

That is, regardless the array substrates 711, 712 disposed on the upper section of the mother glass substrate 101, or the array substrates 731, 741 disposed on the lower section of the mother glass substrate 101, the inspection pad set disposed on the upper section or the lower section of the mother glass substrate 101, rather than the inspection pad set in the middle section of the mother glass substrate 101, can be used for inspecting.

However, under a condition that a mother glass substrate 101, which is similar as the mother glass substrate on which 12 pieces of 17-inch-array substrates are disposed as shown in FIG. 7, is used, and a plurality of 19-inch-array substrates are formed on the mother glass substrate 101, if a method, in which the respective inspection points of the respective 19-inch-array substrates are only connected with the wiring of the inspection pad sets on both the upper and lower sections like the condition of 17-inch-array substrates, is used, then it cannot be inspected like the inspection under the condition of 17-inch-array substrates. It will be described according to the figures as follows.

FIG. 2 is a plan view showing a condition in which 9 pieces of 19-inch-array substrates are disposed on the mother glass substrate as shown in FIG. 7.

In FIG. 2, 202˜204 are the respective exposure regions which are exposed by the same optical mask, respectively, and 101 is a mother glass substrate.

Furthermore, an inspection pad set 121, an array substrate 221 and an inspection pad set 241 are disposed in the exposure region 202 by exposing the exposure region 202. Other exposure regions will be performed similarly.

221˜223 are the array substrates disposed on the upper section of the mother glass substrate, 281˜283 are the array substrates disposed on the middle section of the mother glass substrate, and 291˜293 are the array substrates disposed on the lower section of the mother glass substrate.

Furthermore, 121 is an inspection pad set located on the upper section of the array substrate 221 formed by exposing the exposure region 202, 122 and 123 are also inspection pad sets located on the upper section of the array substrates 222 and 223, respectively.

Also, 241 is an inspection pad set located on the lower section of the array substrate 221 formed by exposing the exposure region 202, 242 and 243 are also the inspection pad sets located on the lower section of the array substrates 222 and 223, respectively.

251 is an inspection pad set located on the upper section of the array substrate 281 formed by exposing the exposure region 203, 252 and 253 are also the inspection pad sets located on the upper section of the array substrates 282 and 283, respectively.

261 is an inspection pad set located on the lower section of the array substrate 281 formed by exposing the exposure region 203, 262 and 263 are also the inspection pad sets located on the upper section of the array substrates 282 and 283, respectively.

271 is an inspection pad set located on the upper section of the array substrate 291 formed by exposing the exposure region 204, 272 and 273 are also the inspection pad sets located on the upper section of the array substrates 292 and 293, respectively.

131 is an inspection pad set located on the lower section of the array substrate 291 formed by exposing the exposure region 204, 132 and 133 are also the inspection pad sets located on the lower section of the array substrates 292 and 293, respectively.

Furthermore, 21 is the inspection point of the array substrate 221 (Indicating by [X] in the figures, similarly hereinafter). 22 is the inspection point of the array substrate 281, 23 is the inspection point of the array substrate 291, 761 is the inspection pad, 762 is also the inspection pad, and all of 765, 766, 763, and 764 are the inspection pads. 31 is wiring for connecting the inspection pad 761, inspection point 21 and inspection pad 762, 32 is wiring for connecting the inspection pad 765, inspection point 22 and inspection pad 766, and 33 is wiring for connecting the inspection pad 763, inspection point 23 and inspection pad 764.

When the respective array substrates on the mother glass substrate as shown in FIG. 2 are inspected, if the inspection can be performed under a condition that only the inspection pad sets 121˜123 existing in the upmost section of the mother glass substrate and the inspection pad sets 131˜133 existing in the downmost section of the mother glass substrate are used, and any set of the inspection pad sets 241˜243, the inspection pad sets 251˜253, the inspection pad sets 261˜263, or the inspection pad sets 271˜273 located in the middle section of the mother glass substrate is not used, then the 19-inch-array substrates will be inspected similarly as the inspection of the 17-inch-array substrates.

In order to inspect the array substrate 221 disposed on the upper section of the mother glass substrate via the inspection point 21, if it is contacted with the inspection pad 761 via the probe block as under the condition that the inspection point 771 is used for inspecting the array substrate 711 of 17-inch-array substrate as shown in FIG. 7, then the inspection will be performed by connecting the wiring 31 with the inspection point 21. For the array substrates 222 and 223, the inspection can be performed similarly by contacting the inspection pads in the inspection pad set 122 or inspection pad set 123.

Under a condition that the array substrate 291 disposed on the downmost section of the mother glass substrate is inspected via the inspection point 23, it is also similar as the inspection of the inspection point 772 as shown in FIG. 7, if it is contacted with the inspection pad 764 as shown in FIG. 7, then the inspection will be performed by connecting the wiring 33 with the inspection point 23. For the array substrates 292 and 293, the inspection can be performed similarly by contacting the inspection pads in the inspection pad set 132 or inspection pad set 133.

That is, for the array substrates disposed on the upmost section or downmost section of the mother glass substrate, under a condition similar as that of 17-inch-array substrates, the inspection can be started from one of any inspection pads in the inspection pad sets 121˜123 or from one of any inspection pads in the inspection pad sets 131˜133.

However, for the array substrates disposed on the middle section of the mother glass substrate, the inspection cannot be started from any inspection pad in the inspection pad sets 121˜123 in the upmost section of the mother glass substrate or the inspection pads in the inspection pad sets 131˜133 in the downmost section of the mother glass substrate like the condition for inspecting the 17-inch-array substrates.

This will be described specifically by an example in which the array substrate 281 is disposed on the middle section of the mother glass substrate.

In order to start the inspection of the array substrate 281 disposed on the middle section of the mother glass substrate as shown in FIG. 2 from any inspection pads in the inspection pad sets 121˜123 or any inspection pads in the inspection pad sets 131˜133, it is required that the inspection point 22 of the array substrate 281 must be connected with any one of the inspection pads in the inspection pad sets 121˜123 or in the inspection pad sets 131˜133. However, the wiring 32 is formed by exposing the exposure region 203, so it cannot be connected with the region outside the exposure region 203 generally. Therefore, the wiring 32 does not connect with any inspection pads among the inspection pads in the inspection pad sets 121˜123 or among the inspection pads in the inspection pad sets 131˜133.

Therefore, the array substrate 281 cannot be inspected by using any inspection pads among the inspection pads in the inspection pad sets 121˜123 in the upmost section of the mother glass substrate or among the inspection pads in the inspection pad sets 131˜133 in the downmost section of the mother glass substrate. It is the same condition for the array substrates 282 and 283.

Next, the inspection point 22 of the array substrate 281 will be taken as an example, to describe an inspection method, which can also be implemented under the above condition.

In order to utilize the inspection point 22 to inspect the array substrate 281 by means of contacting any inspection pad in the inspection pad set 121, the wiring is required to disposed between the inspection point 22 of the array substrate 281 and a specific inspection pad in the inspection pad set 121 as shown in FIG. 2 for connecting the inspection point 22 and the specific inspection pad in the inspection pad set 121.

The region for disposing the wiring formed by exposing the exposure region 202 and the region for disposing the wiring formed by exposing the exposure region 203 traverse between the inspection point of the array substrate 281 and the specific inspection pad in the inspection pad set 121. Therefore, the wiring between the inspection point of the array substrate 281 and the specific inspection pad in the inspection pad set 121 cannot be formed by exposing only the exposure region 202 or the exposure region 203.

However, if the wiring for connecting the specific inspection pad in the inspection pad set 121 formed by exposing the exposure region 202 is connected with the wiring for connecting the inspection point of the array substrate 281 formed by exposing the exposure region 203, the inspection point of the array substrate 281 and the specific inspection pad in the inspection pad set 121 will be connected electrically. This connection can be implemented as following method, that is, to allow the exposure for exposing the exposure region 202 and the exposure for exposing the exposure region 203 to be partly superposed, and the partly superposed region is exposed twice, and the wiring is connected in the dual exposures region. It will be described by referring to the figures as follows.

FIG. 3 is a plan view showing a mother glass substrate under a condition that 3 pieces of 19-inch-array substrates are disposed on a mother glass substrate having the inspection pad as shown in FIG. 7.

In FIG. 3, 361 is an inspection pad included in the inspection pad set 121, 381 is wiring formed by exposing the exposure region 202, 391 is wiring also formed by exposing the exposure region 202, 382 is wiring formed by exposing the exposure region 203, 392 is wiring also formed by exposing the exposure region 203, 383 is wiring formed by exposing the exposure region 204, and 393 is wiring also formed by exposing the exposure region 204. Further, 333 is a dual-exposure-region formed by exposing the superposed portion of the exposure region 202 and the exposure region 203 twice, 334 is a dual-exposure-region formed by exposing the superposed portion of the exposure region 203 and the exposure region 204 twice.

The range of the dual-exposure-region can be adjusted simply by changing the exposure position when it is exposed, so through adjusting the range of the dual-exposure-region 333, the wiring 391 and 382 can be exposed twice in a superposed state, therefore, the electrical connection between a region located above the dual-exposure-region and a region located therebelow can be realized.

This will be described specifically as follows. The wiring 381 and the wiring 391 are fabricated by exposing the exposure region 202. Further, the wiring 382 and the wiring 392 are fabricated by exposing the exposure region 203. Therefore, if the dual exposures is used, and the exposure position in the dual-exposure-region 333 is adjusted to allow the wiring 391 and wiring 382 to be superposed, then the wiring 391 can be connected electrically with the wiring 382.

The inspection pad 361 existing transversely in the exposure region and the inspection point in the array substrate 281 can be connected by utilizing such dual exposures method.

However, it is desired sometimes that the connection must be made in the dual-exposure-region 333 rather than the dual-exposure-region 334 due to different conditions. For example, it is supposed that the array substrate 281 is inspected via the inspection point by utilizing the inspection pad 361. Under such condition, if the wiring is superposed in the dual-exposure-region 334, then the inspection point in the array substrate 291 which is not desired to be connected will be connected, and the array substrate 281 cannot be inspected correctly by utilizing the inspection pad 361.

Referring to the Patent Article 1 for the related prior art: Japanese Publication NO. 8-50295.

### SUMMARY OF THE INVENTION

Therefore, the object of the invention is to provide an optical mask which can be inspected by using the same probe device, array substrates produced by the optical mask, and the manufacturing method of the array substrates, under a condition that a plurality of array substrates is produced on one mother glass substrate by using the same optical mask, the connection and disconnection of the wiring between the adjacent exposure regions can be adjusted freely, and the array substrates having different sizes are configured on the same mother glass substrate.

The optical mask of the invention is used for manufacturing a plurality of TFT array substrates for the liquid crystal display device which can be obtained simultaneously, that is, they are referred to as “array substrates” in short, wherein:

said optical mask comprising: a region in which wiring is formed in the upper end section of the array substrate at up and down direction; that is, a region of the “wiring in the upper section at up and down direction” as described below; a region in which wiring is formed in the lower end section of the array substrate at up and down direction; that is, a region of the “wiring in the lower section at up and down direction” as described below; and a region in which a turning section is formed at either side of at least one of the two wiring, the wiring in said lower section at up and down direction and the wiring in said upper section at up and down direction.

Further, said turning section is a turning section having U shape.

Furthermore, a TFT array substrate used for the liquid crystal display device of the invention, wherein, it is produced by using the above optical mask.

Furthermore, a manufacture method for producing the TFT array substrate used for the liquid crystal display device of the invention, wherein, the above optical mask is used for the exposure process.

If the invention is employed, then under a condition that a plurality of array substrates are produced on one mother glass substrate by using the same optical mask, the connection and disconnection of the wiring between the adjacent exposure regions will be adjusted freely; and even though under a condition that the same mother glass substrate having the array substrates with different sizes disposed thereon is inspected, the same probe device used for inspecting can also be used.

### BRIEF DESCRIPTION OF THE DRAWINGS

FIG. 1 is a plan view of a mother glass substrate showing a general situation that the pads used for inspecting are disposed on the mother glass substrate.

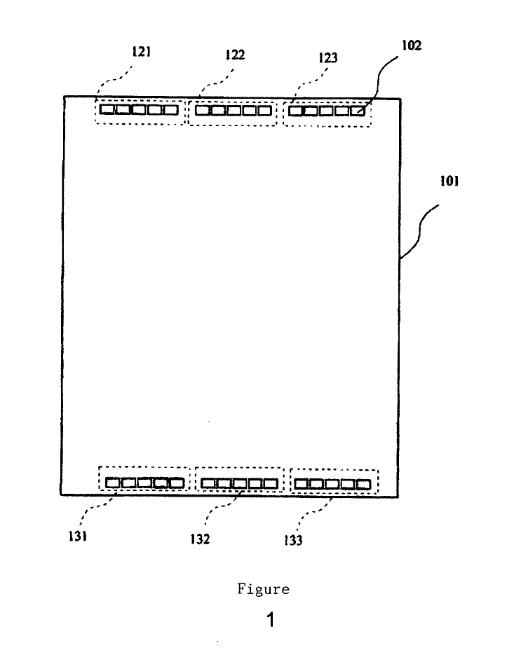

FIG. 2 is a plan view showing a mother glass substrate under a condition in which a plurality of 19-inch-array substrates are disposed on the mother glass substrate having the pads for inspecting as shown in FIG. 1.

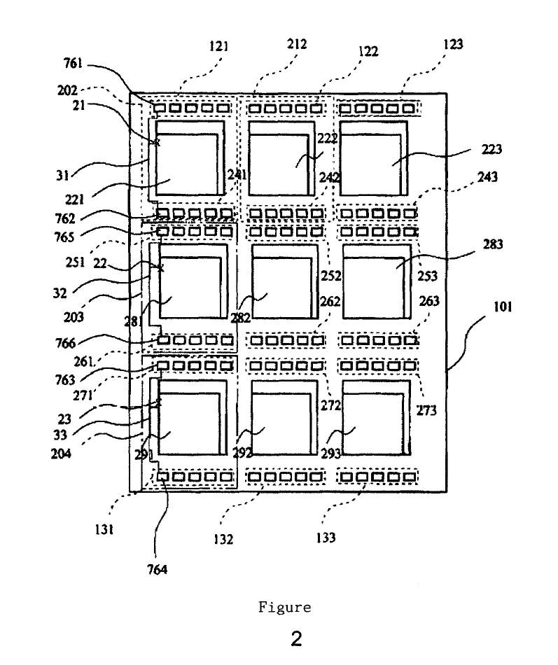

FIG. 3 is a plan view showing a mother glass substrate under a condition that 3 pieces of 19-inch-array substrates are disposed on a mother glass substrate having the inspection pads as shown in FIG. 1.

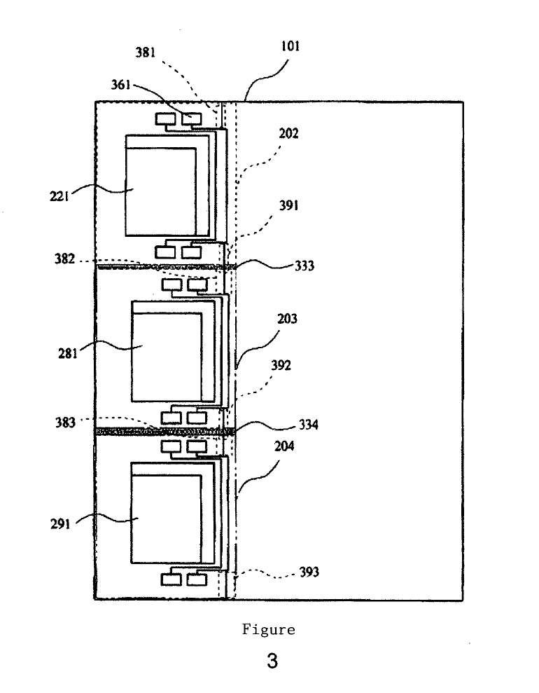

FIG. 4 is a brief plan view of a mother glass substrate having the array substrates, which are configured with an optical mask, disposed thereon, for describing said optical mask according to an embodiment of the invention.

FIG. 5 is an enlarged view of the portion 421 in FIG. 4.

FIG. 6 is an enlarged view of the portion 422 in FIG. 4.

FIG. 7 is a plan outline view of a mother glass substrate having 12 pieces of 17-inch-array substrates disposed thereon.

### EXPLANATION OF SYMBOLS

101: mother glass substrate
202: exposure region
203: exposure region
204: exposure region
221: array substrate
281: array substrate
291: array substrate
361: inspection pad
381: wiring in the upper section at up and down direction
382: wiring in the upper section at up and down direction
383: wiring in the upper section at up and down direction
391: wiring in the lower section at up and down direction
392: wiring in the lower section at up and down direction
393: wiring in the lower section at up and down direction
501: U shape turning section facing the boundary
511: U shape turning section facing the center

### DETAILED DESCRIPTION OF THE INVENTION

The embodiments of the invention will be described by referring to the figures as follows.

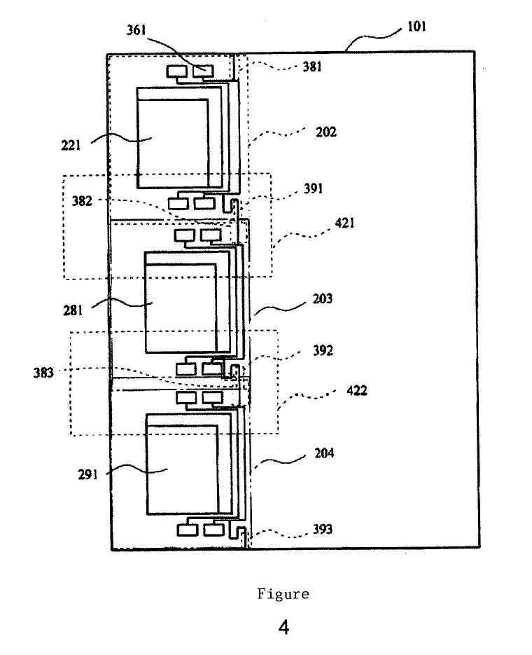

FIG. 4 is a brief plan view of a mother glass substrate having the array substrates, which are configured with an optical mask (Hereinafter also referred to as “the present optical mask”), disposed thereon, for describing said optical mask according to an embodiment of the invention.

In FIG. 4, 101 is a mother glass substrate, 381 is wiring in the upper section at up and down direction produced by using the present optical mask, 391 is wiring in the lower section at up and down direction produced by using the present optical mask

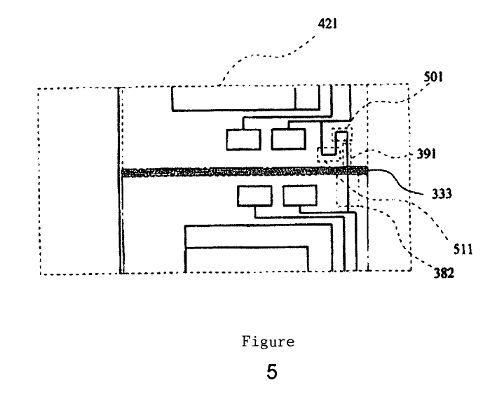

FIG. 5 is an enlarged view of the portion 421 in FIG. 4.

In FIG. 5, 391 is wiring in the lower section at up and down direction formed by exposing the exposure region 202, 501 is U shape turning section facing the boundary, 511 is U shape turning section facing the center, 382 is wiring in the upper section at up and down direction formed by exposing the exposure region 203, 333 is a dual-exposure-region of the exposure region 202 and exposure region 203 that are exposed in a superposing state.

In the dual exposures field, under the condition of the dual-exposure-region 333 as shown in FIG. 5, the wiring 391 in the lower section at up and down direction and the wiring 382 in the upper section at up and down direction are superposed due to the dual exposures, as a result, the wiring 391 in the lower section at up and down direction and the wiring 382 in the upper section at up and down direction can be connected, furthermore, the wiring in the U shape turning section 511, which faces the center, is not disconnected.

The condition in which the wiring in the U shape turning section 511, which faces the center, is disconnected will be described as follows.

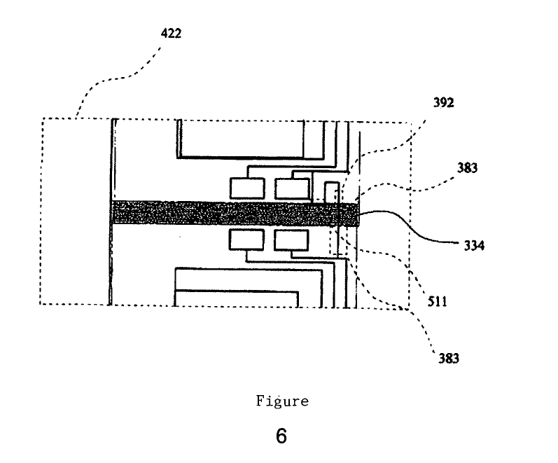

FIG. 6 is an enlarged view of the portion 422 in FIG. 4.

In FIG. 6, 392 is the wiring in the lower section at up and down direction formed by exposing the exposure region 203, 383 is the wiring in the upper section at up and down direction formed by exposing the exposure region 204, 511 is the U shape turning section facing the center formed by exposing the exposure region 203.

The wiring is also formed by exposing twice the dual-exposure-region 334 under the condition of FIG. 6 to allow the wiring 392 in lower section at up and down direction to superpose the wiring 383 in upper section at up and down direction. As a result, the wiring 392 in lower section at up and down direction can be connected with the wiring 383 in upper section at up and down direction, as the same condition in FIG. 5.

However, the wiring is formed in the U shape turning section 511 facing the center within the dual-exposure-region 334 by utilizing one of the dual exposures to expose the exposure region 203, however, the wiring is not formed when exposing the exposure region 204, in this way, in the dual-exposure-region, one exposure forms the wiring, while another exposure does not form the wiring due to the type of the photoresist used in said region.

Therefore, the result of the dual exposures in the U shape turning section 511 facing the center can be controlled by selecting the type of the photoresist, to not allow the wiring to be formed therein, the U shape turning section 511 facing the center does not exist in the connection path between the inspection pad 361 and the wiring 392 in lower section at up and down direction so that the wiring is cut off.

Therefore, when the wiring 392 in lower section at up and down direction is desired to be connected with the inspection pad 361, the dual-exposure-region can be adjusted to allow that the U shape turning section facing the center is not included in the dual-exposure-region, as shown in FIG. 5; and when the wiring 392 in lower section at up and down direction is not desired to be connected with the inspection pad 361, then it can be done with the U shape turning section facing the center to be included in the dual-exposure-region, as shown in FIG. 6.

Under the condition that a plurality of array substrates are fabricated by one mother glass substrate, if the optical mask is used in such a way, then the inspection points of the array substrates formed in the center section of the mother glass substrate can be connected or disconnected with other array substrates by adjusting the dual-exposure-region during the exposure process in which the present optical mask is used.

Therefore, if the invention is used, the wiring can be connected or disconnected freely at the boundaries of different exposure regions, and the inspection points of the respective array substrates can be connected or disconnected freely with the inspection pads in the inspection pad sets disposed in the upper section or lower section of the mother glass substrate.

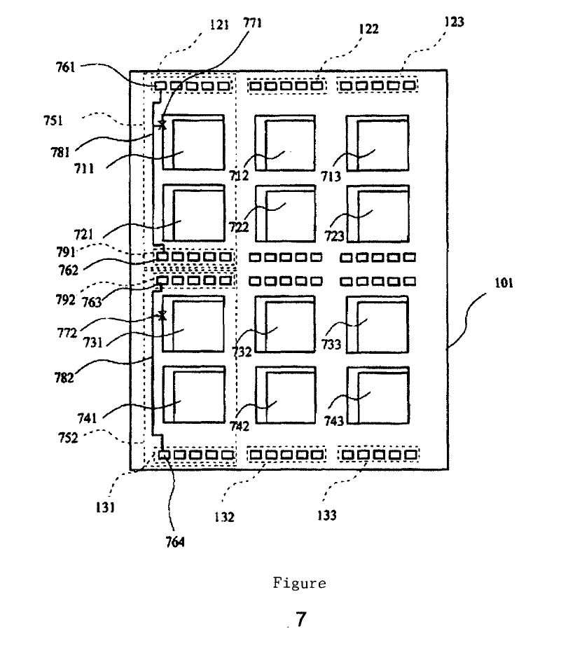

As a result, when the mother glass substrate that is used for fabricating twelve pieces of 17-inch-array substrates as shown in FIG. 7 is employed for fabricating nine pieces of 19-inch-array substrates, the same inspection pads and inspection probe devices as those used under the 17-inch-array substrates condition can also be used for inspecting.

Furthermore, the exposure process is well known without particular features, so the description thereof will be omitted. Furthermore, the inspection probes, and the inspection probe devices are well known without particular features, so the description thereof will be omitted.

What is claimed is:

1. An optical mask used for manufacturing a plurality of TFT array substrates employed by the liquid crystal display device, hereinafter referred to as “array substrates”, wherein:
said optical mask comprising: a region in which wiring is formed in the upper end section of the array substrate and extending at up and down direction; that is, a region of the “wiring in the upper section at up and down direction” as claimed below; a region in which wiring is formed in the lower end section of the array substrate and extending at up and down direction; that is, a region of the “wiring in the lower section at up and down direction” as claimed below; and a region in which a turning section is formed at either side of at least one of the two wiring, the wiring in said lower section at up and down direction and the wiring in said upper section at up and down direction.

2. The optical mask as claimed in claim 1, wherein:
said turning section is a turning section having U shape.

3. A TFT array substrate used for the liquid crystal display device, wherein:
it is produced by using said optical mask as claimed in claim 1.

4. A manufacture method for producing the TFT array substrate used for the liquid crystal display device, wherein, said optical mask as claimed in claim 1 is used for the exposure process.
